(19) United States
(12) Patent Application Publication
(10) Pub. No.: US 2025/0290760 A1
(43) Pub. Date: Sep. 18, 2025

(54) COMPUTER-IMPLEMENTED METHOD AND SYSTEM FOR PLANNING THE TRAJECTORY OF AN EGO VEHICLE

(71) Applicant: Robert Bosch GmbH, Stuttgart (DE)

(72) Inventors: Steffen Hagedorn, Leonberg (DE); Alexandru Paul Condurache, Renningen (DE); Marcel Milich, Reutlingen (DE)

(21) Appl. No.: 19/067,111

(22) Filed: Feb. 28, 2025

(30) Foreign Application Priority Data
Mar. 12, 2024 (DE) 10 2024 202 314.0

(51) Int. Cl. G01C 21/34

(52) U.S. Cl. CPC G01C 21/3415; G01C 21/3492

(57) ABSTRACT

A computer-implemented procedure for planning a trajectory of an ego vehicle in a traffic scenario with at least one other participant. Based on trajectories of all participants, using a DL-based initialization component for each participant, an initial set of equivariant features and an initial set of invariant features are generated. The features of the initial sets are modified using a neural network in parallel interacting branches, in such a way that the equivariant features of the resulting sets map relationships between the participants of the traffic scenario and at least in the modification of the features of the initial set of the ego vehicle. Using a DL-based trajectory decoder, at least one trajectory is predicted for all participants in the traffic scenario, each based on the resulting set of equivariant features. As a result of the planning, a predicted trajectory for the ego vehicle is selected.

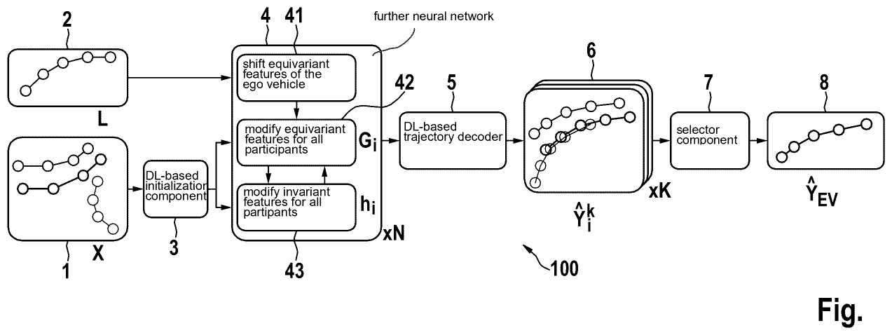

### FIELD

The present invention relates to a computer-implemented method and a computer-implemented system for planning a trajectory Ŷ_{EV} of an ego vehicle in a traffic scenario with at least one other participant.

### BACKGROUND INFORMATION

In order to be able to plan maneuvers that are safe and can be tracked, automated vehicles must anticipate how the current traffic scenario will develop. This is particularly important when there are other participants, such as other vehicles, cyclists and pedestrians, in the traffic scenario. Therefore, it is sought to predict the future behavior of as many participants in the traffic scenario as possible in order to take this into account in the behavioral or trajectory planning of the ego vehicle. For this reason, in recent years the use of machine learning, in particular deep learning (DL)-based models, has become established as the de facto standard for prediction.

### SUMMARY

In the context of the present invention, trajectories are each described on the basis of a sequence of points in Euclidean space. Depending on the application, these are preferably points in 2D or 3D Euclidean space. In addition to the coordinates of the individual waypoints, the trajectory data can also include additional information describing, for example, the movement state of the participant in a waypoint of the trajectory, in particular speed, orientation, etc.

The planning for the ego vehicle is done here based on the trajectories Xᵢ that the individual participants in the traffic scenario have already traveled at the time of planning. Not only are the other participants in the traffic scenario taken into account; the trajectory X₀ that the ego vehicle has traveled is also considered.

In terms of effectiveness and robustness, the predicted trajectories should be independent of the viewing angle of the traffic scenario, i.e. independent of the perspective from which the traffic scenario is viewed. This requirement can be met by using a roto-translation-equivariant prediction model. In such prediction models, a Euclidean transformation-translation, rotation or reflection—of the model input has the same effect on the model output. This means that if the input variables are subjected to a Euclidean transformation, then the prediction result is transformed in the same way, i.e. is also rotated, shifted, or mirrored.

EqMotion (arxiv.org/pdf/2303.10876.pdf) is a roto-translation-equivariant prediction model that predicts the future course of a movement at discrete points in time. For example, it could also be used to predict the behavior of participants in a traffic scenario. However, EqMotion is limited to prediction; it is not designed for planning tasks.

According to an example embodiment of the present invention, it a DL-based roto-translation-equivariant model is used to predict possible developments of a given traffic scenario. Trajectories are predicted in parallel for all participants in the traffic scenario. If the model is trained accordingly, then more complex interactions between the individual participants can also be modeled, in particular interactions between the ego vehicle and other participants. The trajectories predicted for the ego vehicle in this way are then used as a basis for the trajectory planning of the ego vehicle.

For this purpose, according to an example embodiment of the present invention it is provided that for each participant in the traffic scenario, with the aid of a DL-based initialization component an initial set Gᵢ⁽⁰⁾ of first features and an initial set hᵢ⁽⁰⁾ of second features are produced, based on the trajectories Xᵢ of all participants already traveled at the time of planning. According to the present invention, the initialization component is designed and trained in such a way that the first features are equivariant and the second features are invariant with respect to Euclidean transformations of the trajectories Xᵢ.

The participant trajectories Xᵢ are thus mapped into a latent space, which, however, can still be assigned to the Euclidean initial space in that each initial set Gᵢ⁽⁰⁾ represents a Cx2 or Cx3 tensor, where C is the feature embedding dimension and describes the number of 2D or 3D points in the latent space.

Translational equivariance is achieved by moving the coordinate origin to the center of all positions before a linear transformation is carried out. Rotational equivariance follows from the associative law of matrix multiplication, which is also valid for processing with fully connected layers (FCL).

According to an example embodiment of the present invention, the features of the initial sets Gᵢ⁽⁰⁾ and of the initial sets hᵢ⁽⁰⁾ are then modified step by step in parallel but interacting branches using at least one likewise roto-translation-equivariant neural network, in such a way that the equivariant features of the resulting sets Gᵢ^{(N)} map relationships between the participants in the traffic scenario.

The equivariance of the initial sets Gᵢ⁽⁰⁾ and the invariance of the initial sets hᵢ⁽⁰⁾ with respect to Euclidean transformations of the trajectories Xᵢ are therefore also preserved with these modifications.

According to an example embodiment of the present invention, in the modification of the features of the initial set G₀⁽⁰⁾ of the ego vehicle, an item of destination information specified for the ego vehicle is also taken into account.

With the help of at least one DL-based trajectory decoder, trajectories Ŷᵢ are then predicted on the basis of the resulting sets Gᵢ^{(N)} of equivariant features in a prediction step for all participants in the traffic scenario, namely at least one trajectory Yi for each participant.

At least one trajectory Ŷ₀ is also predicted for the ego vehicle. Since the set G₀^{(N)} on which this prediction is based maps relationships between all participants in the traffic scenario, possible interactions with other participants in the traffic scenario are also taken into account in the prediction for the ego vehicle.

According to an example embodiment of the present invention, from all trajectories Ŷ₀ predicted for the ego vehicle, at least one trajectory Ŷ_{EV} is selected as a result of the planning.

According to an example embodiment of the present invention, prediction and planning go hand in hand, since the selection of a trajectory previously predicted for the ego vehicle does not have to be learned, but can simply be done on the basis of rules.

As mentioned above, the behavioral prediction and planning are based on trajectories Xᵢ that the individual participants in the traffic scenario have already traveled at the time of planning. These trajectories Xᵢ traveled by the individual participants are usually ascertained on the basis of sensor data that are recorded by a perception module of the ego vehicle and evaluated accordingly. The trajectories Xᵢ can for example be determined as part of an environment model.

In a preferred embodiment of the present invention, for the modification of the features of the initial sets Gᵢ⁽⁰⁾ and of the initial sets hᵢ⁽⁰⁾, a graph-based neural network GNN (graph neural network) is used, which includes N fully connected layers FCL. This realizes two interacting processing branches, namely a processing branch for the equivariant features Gᵢ, such as vehicle positions and a processing branch for the invariant features hᵢ, such as distances between two vehicle positions.

GNNs are particularly well suited to detecting and predicting relationships and dependencies between past and future behaviors of individual participants in the traffic scenario.

It is substantial to the present invention that, in the modification of the features of the initial set G₀⁽⁰⁾ of the ego vehicle, an item of destination information specified for the ego vehicle is taken into account. The form in which the destination information is specified depends substantially on the application and the specific implementation. For example, the destination information could be provided in the form of route information as ascertained by a navigation system based on the starting point, destination and map information. However, the destination information could also simply consist of a direction indication, such as northbound, or a destination point, such as the next intersection in the direction of travel. Destination information in the form of behavioral instructions is also possible, e.g., turn left.

In a particularly advantageous variant of the present invention, on the basis of the specified destination information, a tensor L is generated which describes the destination information in the form of a route and has the same dimensions as the initial sets Gᵢ⁽⁰⁾ of equivariant features. Accordingly, a number C of 2D or 3D waypoints of a destination route are generated on the basis of the target information, where the number C corresponds to the feature embedding dimension C of the initial sets Gᵢ⁽⁰⁾. If the destination information is given by more or fewer waypoints, it can easily be converted into a Cx2 or Cx3 tensor representation by interpolation.

It has been recognized that, with the aid of such a tensor L, the destination information can be fed into the neural network to modify the features of the initial sets Gᵢ⁽⁰⁾ and the initial sets hᵢ⁽⁰⁾ in such a way that this information is taken into account during the modification. For this purpose, in each modification step a difference (L-G₀⁽¹⁾) is formed between the tensor L and the corresponding set G₀⁽¹⁾. This difference (L-G₀⁽¹⁾) is then optimized in the step-by-step modification of the initial set G₀⁽⁰⁾. This optimization also affects the sets Gᵢ⁽¹⁾ and the initial sets hᵢ⁽¹⁾ of the other participants since, according to the present invention, they are modified step by step in parallel but interacting branches.

In a preferred embodiment of the present invention, different possible developments of the traffic scenario are taken into account when predicting the behavior of the individual participants, which is referred to as multimodal prediction. In this case, using one or more DL-based trajectory decoders, a plurality of trajectories Ŷᵢ^{k} is predicted for at least one participant in the traffic scenario, which trajectories represent different developments in the traffic scenario.

In this context, according to an example embodiment of the present invention, it is particularly advantageous if for each predicted trajectory Ŷᵢ^{k} at least one evaluation variable Pᵢ^{k} is also predicted. These evaluation variables Pᵢ^{k} can then be taken into account during planning, i.e. when selecting one or more trajectories predicted for the ego vehicle as the planning result Ŷ_{EV}.

In addition, according to an example embodiment of the present invention, the evaluation variables Pᵢ^{k}, which are predicted together with the trajectories Ŷᵢ^{k} of different modalities, represent the probabilities of occurrence of the different modalities. In the case of the trajectories Ŷ₀ predicted for the ego vehicle, the evaluation variables Pᵢ^{k} can be used for quality assessment.

### BRIEF DESCRIPTION OF THE DRAWING

Exemplary embodiments and advantageous developments of the present invention are explained in more detail below in conjunction with the single FIGURE.

The FIGURE shows a schematic block diagram of a computer-implemented system 100 according to an example embodiment of the present invention for planning a trajectory Ŷ_{EV} of an ego vehicle in a traffic scenario with at least one other participant.

The planning method according to an example embodiment of the present invention is explained in more detail below with reference to the single FIGURE.

### DETAILED DESCRIPTION OF EXAMPLE EMBODIMENTS

The system 100 according to the present invention shown in the single FIGURE is part of a vehicle, which is referred to below as the ego vehicle. The system 100 is used for the trajectory planning of the ego vehicle. According to the present invention, the trajectory planning is based on the trajectories Xᵢ that the individual participants i in the given traffic scenario have already traveled at the time of planning.

The trajectories traveled Xᵢ 1 are ascertained using a perception layer of the system 100, which is not shown in detail here. It is substantial that both the trajectory X₀ traveled by the ego vehicle (i=0) as well as the trajectories Xᵢ traveled by the other participants (i≠0) in the traffic scenario are ascertained. For this purpose, the perception layer usually includes a plurality of different sensors, such as video, radar and/or lidar sensors, and possibly also inertial sensors, in order to aggregate scenario-specific information. With appropriate communication connections and access rights of the perception layer, the information collected by the vehicle's own sensors can also be supplemented by information from sources external to the vehicle, such as infrastructure sensors, GPS positioning, map information, etc. Based on the scenario-specific information aggregated in this way, the perception layer generates an environment model of the traffic scenario and its development up to the time of planning. Based on the aggregated scenario-specific information, object detection is carried out in order to identify and locate the individual participants as such and thus to determine their traveled trajectories Xᵢ 1, where each trajectory Xᵢ 1 is described here as a sequence of points in 2D Euclidean space.

Furthermore, the system 100 comprises a destination specification module with an input interface for destination information relating to the ego vehicle. In principle, this destination information can be specified in different forms, e.g. in the form of route information of a navigation system, in the form of an item of direction information or a destination to be headed for, or in the form of a behavioral instruction, such as turn left or drive straight ahead.

In the embodiment described here, however, the destination specification module does not have only the function of an input interface. It also converts the destination information into a format suitable for further processing, which is explained in more detail below. The result of this transformation, i.e. the output of the destination specification module, is designated 2 in the single FIGURE.

The trajectories Xᵢ 1 ascertained using the perception layer are fed to a DL-based initialization component 3 designed such that based on the trajectories Xᵢ 1 of all participants, for each participant an initial set Gᵢ⁽⁰⁾ of first features and an initial set hᵢ⁽⁰⁾ of second features are produced, wherein the first features are equivariant and the second features are invariant with regard to Euclidean transformations of the trajectories Xᵢ.

In this way, the participant trajectories Xᵢ 1 are mapped into a latent space which can however still be assigned to the 2D Euclidean initial space in that each initial set Gᵢ⁽⁰⁾ represents a Cx2 tensor, where C is the feature embedding dimension, which corresponds to the number of 2D points in the latent space.

This initialization enables a roto-translation-equivariant behavioral prediction for the individual participants of the traffic scenario based on the totality of the trajectories Xᵢ 1 traveled.

The basic idea of the roto-translation-equivariant treatment or processing of point sequences in Euclidean space is to shift the viewpoint to the center, i.e. to the center of gravity [symbol] .

To return to the original coordinate system after the transformation, the center of gravity [symbol] is added again. Accordingly, each initial set G; (0) can be described as:

$${G}_{i}^{( 0 )} = {ϕ}_{{init}_{g}} ( {X}_{i} - \overline{𝕏} ) + \overline{𝕏} ∈ {ℝ}^{C \times 2} \qquad ( 1 )$$

The function ϕinit_{g} is realized here by a fully connected layer FCL of the neural network of the initialization component 3, thus ensuring the roto-translation equivariance. An FCL always performs a linear transformation of the input data and can be easily expressed in the form of a matrix multiplication.

In addition, invariant features of the individual participants i are also initialized, namely a function that can be derived from the waypoints of the ascertained trajectories Xᵢ and is composed of the speed ΔXᵢ and the orientation angle (Δxi_{τ}, ΔXᵢ^{τ}, ΔXᵢ^{τ-1}) of the participant i.

$${h}_{i}^{( 0 )} = {ϕ}_{{init}_{g}} ( [ {‖ Δ {X}_{i} ‖}_{2} ; angle ( Δ {X}_{i}^{τ} , Δ {X}_{i}^{τ - 1} ) ] ) ∈ {ℝ}^{D} \qquad ( 2 )$$

Like the function ϕinit_{g}, the functions ϕinitₕ are also realized by an FCL of the neural network of the initialization component 3, thus ensuring the invariance of the transformation.

The initialization component 3 could also have learned to take into account relationships cᵢⱼ between individual participants i and j, such as differences in distance, speed and/or orientation between the individual participants i and j, when generating the initial sets Gᵢ⁽⁰⁾ and hᵢ⁽⁰⁾.

As mentioned above, the destination specification module of the embodiment described here converts a given item of destination information into a format suitable for further processing, namely the format of the initial set Gᵢ⁽⁰⁾, i.e. into a Cx2 tensor. This enables a roto-translation-equivariant adaptation of the trajectory planning to the specified destination for the ego vehicle.

In the exemplary embodiment described here, the ego vehicle has a tactical planner or a navigation system that, upon request, provides a rough route plan based on a road map, here in the form of any number of 2D waypoints. This rough route planning is provided here as destination information for the ego vehicle. The destination specification module maps the corresponding 2D waypoints onto a set of C 2D waypoints by suitable interpolation, where the number C is determined by the dimension of the tensor Gᵢ⁽⁰⁾. The resulting set of C 2D waypoints forms a tensor L, which is also referred to in the following as the high-level route L 2.

Both the high-level route L as well as the initial sets Gᵢ⁽⁰⁾ and hᵢ⁽⁰⁾ of equivariant and invariant features are fed to a further neural network 4 of the system 100. The neural network 4 is implemented here in the form of a GNN and comprises N so-called feature update blocks, which are run through one after the other. Each of the N feature update blocks is realized here by a plurality of operations. The learnable part of each of these operations is realized by an FCL. In addition, the feature update blocks also, however, reflect deliberately introduced decisions, such as a summation of all neighbors.

It should be noted at this point that, in principle, all operations of the feature update blocks could also be learned by the GNN 4.

Due to this configuration of the GNN 4, the successive modification of the initial features Gᵢ⁽⁰⁾ and hᵢ⁽⁰⁾ is equivariant or invariant overall with respect to Euclidean transformations of the trajectories Xᵢ 1. The superscript (l) denotes the l-th FCL of the GNN 4, or the 1-th modification step.

According to the present invention, the GNN 4 was designed and trained such that it modifies the features of the initial sets Gᵢ⁽⁰⁾ and of the initial sets hᵢ⁽⁰⁾ in parallel but interacting branches, such that the equivariant features of the resulting sets Gᵢ^{(N)} map relationships between the participants of the traffic scenario, and also the specified destination information is taken into account, at least in the modification of the equivariant features of the initial set G₀⁽⁰⁾ of the ego vehicle.

In the embodiment described here, the equivariant features G₀^{(l)} of the ego vehicle are to be shifted in the latent space in the direction of the high-level route L, namely successively with the aid of the individual FCLs of the GNN 4, which are run through one after the other and each modify the result of the previous layer. For this reason, during the training of the GNN 4, among other things the vectors (L-G₀^{(l)}) between the high-level route L and the output of the corresponding FCL layer were optimized.

In each modification step, first the equivariant features G₀^{(l)} of the ego vehicle are shifted in the direction of the high-level route L, which is illustrated by block 41. Only then is the interaction with the other participants in blocks 42 and 43 taken into account. Thus, in block 42 the modification of the equivariant features takes place for all participants, i.e. for all sets Gᵢ^{(l)}, and in block 43 the modification of the invariant features takes place for all participants, i.e. for all sets hᵢ^{(l)}. These modifications are not carried out independently of each other, but occur in parallel and in interacting fashion, as is indicated by the corresponding arrows in Block 4. This modification sequence leads to a prioritization of interactions between participants over compliance with the route planning of the ego vehicle.

Before describing blocks 41, 42 and 43 in detail, it should be noted that all functions ϕ^{(l)} of these blocks are each realized by an FCL of the GNN 4, which ensures the roto-translation-equivariance of the modifications.

In block 41, only the equivariant features G₀^{(l)} of the ego vehicle are modified, because destination information, or a high-level route L, is only available for the ego vehicle. The modification in block 41 can be described as follows:

$${f}_{ra} : {G}_{0}^{( l )} ← {G}_{0}^{( l )} + {ϕ}_{ra}^{( l )} ( L - {G}_{0}^{( l )} ) ∈ {ℝ}^{C \times 2} . \qquad ( 3 )$$

The input for the function ϕᵣₐ^{(l)}, or the corresponding FCL, is formed by the vector (L-G₀^{(l)}), which points from the embedding of the equivariant features of the ego vehicle in the direction of the destination information in the form of the high-level route L.

The following equation (4) shows that the feature modification in block 41 satisfies the equivariance condition:

$$\begin{matrix}{f}_{ra} ( x R + t ) = {G}_{0}^{( l )} R + t + {ϕ}_{ra} ( LR + t - ( {G}_{0}^{( l )} R + t ) ) \\ = {G}_{0}^{( l )} R + t + {ϕ}_{ra} ( ( L - {G}_{0}^{( l )} ) R ) \\ = {G}_{0}^{( l )} R + t + {ϕ}_{ra} ( L - {G}_{0}^{( l )} ) R \\ = ( {G}_{0}^{( l )} + {ϕ}_{ra} ( L - {G}_{0}^{( l )} ) ) R + t \\ = {f}_{ra} ( x ) R + t □\end{matrix} \qquad ( 4 )$$

The modification of the equivariant features—sets Gᵢ^{(l)}—of all participants i in block 42 comprises an inner aggregation and a neighbor aggregation. In the inner aggregation, the equivariant features Gᵢ^{(l)} of each participant i are modified with a weighting that is calculated based on the invariant features hᵢ^{(l)} of the particular participant i.

$${G}_{i}^{( l )} ← {ϕ}_{att}^{( l )} ( {h}_{i}^{( l )} ) \cdot ( {G}_{i}^{( l )} - {\overline{𝔾}}^{( l )} ) + {\overline{𝔾}}^{( l )} ∈ {ℝ}^{C \times 2} \qquad ( 5 )$$

Here, G̅^{(l)} is the center or the middle position of the equivariant features Gᵢ^{(l)} of the participant i.

In neighbor aggregation, an edge weight eᵢⱼ is first defined for each neighbor i, j on the basis of relationship features cᵢⱼ as well as the equivariant and invariant features, where K stands for the number of different relationships described by relationship features.

$${e}_{ij}^{( l )} = {\sum }_{k = 1}^{K} {c}_{ij , k} {ϕ}_{e , k}^{( l )} ( {h}_{i}^{( l )} ; {h}_{j}^{( l )} ; {‖ {G}_{i}^{( l )} - {G}_{j}^{( l )} ‖}_{2} ) ∈ {ℝ}^{C} \qquad ( 6 )$$

The i-th equivariant feature is then modified using a weighted sum over all its neighbors Nᵢ, as follows:

$${G}_{i}^{( l )} ← {G}_{j}^{( l )} + {\sum }_{j ∈ {𝒩}_{i}} {e}_{ij}^{( l )} \cdot ( {G}_{i}^{( l )} - {G}_{j}^{( l )} ) ∈ {ℝ}^{C \times 2} \qquad ( 7 )$$

Finally, as described in EqMotion

(https://arxiv.org/pdf/2303.10876.pdf), an equivariant non-linear function is applied to produce the input Gᵢ^{(l+1)} for the next FCL.

For the modification of the invariant features—sets hᵢ^{(l)}—in block 43, reference is also made to EqMotion

(https://arxiv.org/pdf/2303.10876.pdf). This modification can be described as follows:

$${P}_{i}^{( l )} = {\sum }_{j ∈ {𝒩}_{i}} {ϕ}_{m}^{( l )} ( [ {h}_{i}^{( l )} ; {h}_{j}^{( l )} ; {‖ {G}_{i}^{( l )} - {G}_{j}^{( l )} ‖}_{2} ] ) ∈ {ℝ}^{D} \qquad ( 8 )$$

$${h}_{i}^{( l + 1 )} = {ϕ}_{h}^{( l )} ( [ {h}_{i}^{( l )} ; {p}_{i}^{( l )} ] ) ∈ {ℝ}^{D} \qquad ( 9 )$$

For the subsequent prediction, however, only the resulting sets of equivariant features Gᵢ^{(N)} of the individual participants i are used.

In the exemplary embodiment described here, the system 100 comprises a DL-based trajectory decoder 5 in the form of K FCLS operating in parallel, each of which is described as a function ϕ_{dec}^{k}. Each of these FCLS ϕ_{dec}^{k} predicted a mode k, i.e. a possible development of the given traffic scenario. For this purpose, at least one trajectory Ŷᵢ^{k} 6 is predicted in a common prediction step for all participants i of the traffic scenario, based namely on the resulting sets of equivariant features Gᵢ^{(N)}.

The superscript k here denotes the k-th FCL of the trajectory decoder 5, or the k-th predicted mode. The prediction of a trajectory Ŷᵢ^{k} can be described as follows:

$${\hat{Y}}_{i}^{k} = {ϕ}_{dec}^{k} ( {G}_{i}^{N} - {\overline{𝔾}}^{N} ) + {\overline{𝔾}}^{N} ∈ {ℝ}^{( {T}_{f} + 1 ) \times 2} \qquad ( 10 )$$

The regression of the trajectories Ŷᵢ^{k} is therefore carried out for all participants in parallel and multi-modally, i.e. multiple alternative future scenarios are regressed in parallel.

It is of particular advantage that the trajectory decoder 5 has been trained such that, for each predicted trajectory Ŷᵢ^{k}, it predicts at least one additional “waypoint” as an evaluation variable. Accordingly, every predicted trajectory Ŷᵢ^{k} goes beyond the actual prediction horizon T_{f}. An evaluation variable Pⁱk for the predicted trajectory Ŷⁱk is derived from the additional “waypoint” by averaging this 2D coordinate over both dimensions:

$${P}_{i}^{k} = {mean}_{C} ( {\hat{Y}}_{i}^{k , {T}_{f} + 1} ) ∈ {ℝ}^{K} \qquad ( 11 )$$

The variable Pᵢ^{k} is an indicator of the probability of occurrence of mode k.

Finally, the system 100 also comprises a selector component 7, which is designed such that it selects at least one trajectory as a planning result Ŷ_{EV} 8 from the trajectories Ŷ₀^{k} predicted for the ego vehicle. The selector component takes into account the predicted evaluation variables P₀^{k}, which can be interpreted as probabilities of occurrence for the different modalities. The selector component described here makes the selection of the planning result Ŷ_{EV} 8 in rule-based fashion, as follows:

$${\hat{Y}}_{EV} = {\hat{Y}}_{0}^{{k}^{*}} where {k}^{*} = {arg max {P}_{0}^{{k}^{*}}}_{k = 1 , … , K} \qquad ( 12 )$$

The exemplary embodiment described above illustrates that, according to the present invention, a roto-translation-equivariant combination of trajectory prediction and planning is proposed, wherein in a prediction step trajectories are predicted for all participants of a traffic scenario. This also makes it possible to model more complex interactions between the participants in the traffic scenario. The actual trajectory planning then consists only in the selection of at least one trajectory predicted for the ego vehicle. Roto-translation-equivariant means that when there is a Euclidean transformation of the input trajectories, the predicted or planned trajectories are transformed in the same way.

This allows the amount of training data to be reduced, and the number of learnable weights of the required neural networks can also be reduced.

1-15. (canceled)

16. A computer-implemented method for planning a trajectory Ŷ_{EV} of an ego vehicle in a traffic scenario with at least one other participant, wherein trajectories are each described on based on a sequence of points in Euclidean space, and wherein the planning takes place based on trajectories Xᵢ which individual participants including the ego vehicle and the at least one other participant, have already traveled at a time of the planning, the method comprising the following steps:
generating, based on the trajectories Xᵢ of all participants using a DL-based initialization component, for each participant, an initial set Gᵢ⁽⁰⁾ of first features and an initial set hᵢ⁽⁰⁾ of second features, wherein the first features are equivariant and the second features are invariant with respect to Euclidean transformations of the trajectories Xᵢ;
modifying the first features of the initial sets Gᵢ⁽⁰⁾ and the second features of the initial sets hᵢ⁽⁰⁾ step by step using at least one neural network in parallel but interacting branches in such a way that the equivariance or the invariance with respect to Euclidean transformations of the trajectories Xᵢ is preserved, and such that equivariant features of resulting sets Gᵢ^{(N)} map relationships between the participants in the traffic scenario, wherein, at least in the modification of the first features of the initial set G₀⁽⁰⁾ of the ego vehicle, an item of destination information specified for the ego vehicle is also taken into account;
predicting in a predicting step, using at least one DL-based trajectory decoder, at least one trajectory Ŷᵢ for all participants in the traffic scenario, based in each case on the resulting sets Gᵢ^{(N)} of equivariant features; and
selecting at least one trajectory Ŷ₀ predicted for the ego vehicle as a result Ŷ_{EV} of the planning.

17. The method according to claim 16, wherein the trajectories Xᵢ traveled by the participants in the traffic scenario are determined based on sensor data that have been recorded and evaluated by a perception module of the ego vehicle.

18. The method according to claim 16, wherein the modification of the first features of the initial sets Gᵢ⁽⁰⁾ and the second features of the initial sets hᵢ⁽⁰⁾ takes place using at least one graph-based neural network (GNN), which includes N fully connected layers (FCL).

19. The method according to claim 16, wherein the item of destination information is specified in the form of route information, and/or direction information, and/or a destination point to be approached, and/or a behavioral specification.

20. The method according to claim 16, wherein, based on the specified destination information, a tensor L is generated which describes the destination information in a form of a route and has the same dimensions as the initial sets Gᵢ⁽⁰⁾ of equivariant features.

21. The method according to claim 20, wherein the specified destination information is taken into account in the modification of the features of the initial set G₀⁽⁰⁾ of the ego vehicle in that, in each modification step, a difference (L-G₀^{(l)}) is formed between the tensor L and a corresponding set G₀^{(l)} and the difference (L-G₀^{(l)}) is optimized in the step-by-step modification of the initial set G₀⁽⁰⁾ of the ego vehicle.

22. The method according to claim 16, wherein, using the at least one DL-based trajectory decoder, a plurality of trajectories Ŷᵢ^{k} of different modalities is predicted for at least one participant in the traffic scenario, the trajectories representing different developments in a traffic scenario.

23. The method according to claim 22, wherein, using the at least one DL-based trajectory decoder, for each predicted trajectory Ŷᵢ^{k}, at least one evaluation variable Pᵢ^{k} is predicted, and at least one trajectory Ŷ₀^{k} predicted for the ego vehicle is selected as a result Ŷ_{EV} of the planning, taking into account the predicted evaluation variables P₀^{k}.

24. The method according to claim 23, wherein the evaluation variables Ŷ_{EV}, which are predicted together with the trajectories Ŷᵢ^{k} of the different modalities, represent the probabilities of occurrence of the different modalities and, in the case of the trajectories Ŷ₀ predicted for the ego vehicle, are used to assess quality.

25. A computer-implemented system for planning a trajectory Ŷ_{EV} of an ego vehicle in a traffic scenario with at least one other participant, the system comprising:
a destination specification module configured to specify an item of destination information for the ego vehicle;
a perception layer configured to ascertain trajectories Xᵢ traveled by the individual participants, including the ego vehicle and the at least one other participant, based on aggregated scenario-specific information;
a DL-based initialization component configured to produce, based on the trajectories Xᵢ of all participants, for each participant, an initial set Gᵢ⁽⁰⁾ of first features and an initial set hᵢ(⁰⁾ of second features, wherein the first features are equivariant and the second features are invariant with respect to Euclidean transformations of the trajectories Xᵢ;
a neural network configured to:
modify the first features of the initial sets Gᵢ⁽⁰⁾ and second features of the initial sets hᵢ⁽⁰⁾ in parallel but interacting branches in such a way that the equivariance or the invariance with respect to Euclidean transformations of the trajectories Xᵢ is preserved, and equivariant features of resulting sets Gᵢ^{(N)} map relationships between the participants in the traffic scenario, and
take into account, at least in the modification of the first features of the initial set G₀⁽⁰⁾ of the ego vehicle, the specified destination information;
at least one AI-based trajectory decoder configured to predict in a prediction step, based on the resulting sets Gᵢ^{(N)} of equivariant features, at least one trajectory Ŷᵢ each for all the participants of the traffic scenario; and
a selector component configured to select a trajectory Ŷ₀ predicted for the ego vehicle as a result Ŷ_{EV} of the planning.

26. The system according to claim 25, wherein the neural network is a graph-based neural network (GNN) that includes N fully connected layers (FCL).

27. The system according to claim 25, wherein:
the destination specification module is configured to generate a tensor L based on a specified item of destination information which describes the destination information in a form of a route and has the same dimensions as the sets of equivariant features G₀^{(l)} generated for the ego vehicle, and
the neural network has been trained in such a way that a difference (L-G₀^{(l)}) between the tensor L and a corresponding set G₀^{(l)} is optimized in a step-by-step modification of the initial set G₀⁽⁰⁾ of the ego vehicle

28. The system according to claim 25, wherein K DL-based trajectory decoders operating in parallel are provided, which in each case predict at least one trajectory Ŷᵢ^{k} for all participants in the traffic scenario, in each case for one of K possible developments of a traffic scenario.

29. The system according to claim 28, wherein each DL-based trajectory decoder has been trained such that, for each predicted trajectory Ŷᵢ^{k}, the DL-based trajector decoder predicts at least one evaluation variable Pᵢ^{k}, and the selector component is configured to, in the selection of the planning result Ŷ_{EV}, take into account the predicted evaluation variables Pᵢ^{k}.

30. A vehicle with a computer-implemented system for planning a trajectory Ŷ_{EV} of an ego vehicle in a traffic scenario with at least one other participant, the system comprising:
a destination specification module configured to specify an item of destination information for the ego vehicle;
a perception layer configured to ascertain trajectories Xᵢ traveled by the individual participants, including the ego vehicle and the at least one other participant, based on aggregated scenario-specific information;
a DL-based initialization component configured to produce, based on the trajectories Xᵢ of all participants, for each participant, an initial set Gᵢ⁽⁰⁾ of first features and an initial set hᵢ(⁰⁾ of second features, wherein the first features are equivariant and the second features are invariant with respect to Euclidean transformations of the trajectories Xᵢ;
a neural network configured to:
modify the first features of the initial sets Gᵢ⁽⁰⁾ and second features of the initial sets hᵢ⁽⁰⁾ in parallel but interacting branches in such a way that the equivariance or the invariance with respect to Euclidean transformations of the trajectories Xᵢ is preserved, and equivariant features of resulting sets Gᵢ^{(N)} map relationships between the participants in the traffic scenario, and
take into account, at least in the modification of the first features of the initial set G₀⁽⁰⁾ of the ego vehicle, the specified destination information;
at least one AI-based trajectory decoder configured to predict in a prediction step, based on the resulting sets Gᵢ^{(N)} of equivariant features, at least one trajectory Ŷᵢ each for all the participants of the traffic scenario; and
a selector component configured to select a trajectory Ŷ₀ predicted for the ego vehicle as a result Ŷ_{EV} of the planning.
